(19) United States
(12) Patent Application Publication
(10) Pub. No.: US 2015/0179801 A1
(43) Pub. Date: Jun. 25, 2015

(54) THIN FILM TRANSISTOR AND METHOD FOR MANUFACTURING THE SAME

(71) Applicant: SHENZHEN CHINA STAR OPTOELECTRONICS TECHNOLOGY CO. LTD., Shenzhen, Guangdong (CN)

(72) Inventor: Sai-Chang Liu, Shenzhen (CN)

(21) Appl. No.: 14/241,355

(22) PCT Filed: Jan. 17, 2014
(86) PCT No.: PCT/CN2014/070844

§ 371 Date: Feb. 26, 2014

(30) Foreign Application Priority Data
Dec. 25, 2013 (CN) 201310726226.5

(51) Int. Cl. H01L 29/786; H01L 29/66; H01L 21/02

(52) U.S. Cl. CPC H01L 29/7869; H01L 29/78606; H01L 21/02274; H01L 29/66969

(57) ABSTRACT

The present disclosure provides a thin film transistor and a method of manufacturing the same. The transistor includes:a substrate; a gate electrode, a source electrode, and a drain electrode; and an oxide semiconductor layer; wherein, the oxide semiconductor includes a source region and a drain region which electrically contact with the source electrode and the drain electrode respectively, and a channel region for providing a conductive channel between the source electrode and the drain electrode, wherein, a gate isolation layer is arranged between the oxide semiconductor layer and the gate region electrically contacting with the gate electrode, and an oxide semiconductor protective layer is arranged on the oxide semiconductor layer. The transistor in the present disclosure can prevent the oxide semiconductor layer from being damaged during the process of manufacturing, and thus improve the conductive of the device and its integrity.

### FIELD OF THE INVENTION

The present disclosure relates to the technical field of manufacturing semiconductors, and particularly, to a thin film transistor and a method for manufacturing the same.

### BACKGROUND OF THE INVENTION

At present, Thin Film Transistors (TFT for short) are widely used in Integrated Circuits (IC for short) and image display driving circuits, due to their excellent performance. A channel layer of a transistor, as a channel for transmitting charges between a source and a drain of a TFT device, is an important structure of the TFT device. The structure and performance of the channel layer directly affect the electrical performance of a product being made of the device. The channel layer may be consisted of a semiconductor thin film material which is known as a silicon-based semiconductor material, as well as an oxide semiconductor material, etc. An example of the oxide semiconductor material is Indium Gallium Zinc Oxide (IGZO for short).

Moreover, according to the ways by which the source/drain electrode is contacting with an active layer, the TFT may be divided into a TFT with top gate structure and a TFT with bottom gate structure, as shown in FIGS. 1a and 1b. However, during manufacturing each TFT, it must be suffered multiple times of high temperature processes and contact with lots of chemical reagents. Accordingly, it is inevitable for an oxide semiconductor layer 14, namely the foregoing channel layer, to be affected by the process of manufacturing. For example, during the manufacturing of thin film transistors with a structure of top gate bottom contact, a Gate Isolation (GI for short) layer 12 or a PV (Passivation) layer 11 is generally grown on the deposited oxide semiconductor layer 14 through a Plasma Enhanced Chemical Vapor Deposition (PECVD for short) process. During this process, the oxide semiconductor is directly exposed in a plasma environment, which easily leads to interface damage on the oxide semiconductor surface and decreases the electric performance of the channel of the device, so that the performance of the device is degraded.

Therefore, it is necessary to provide a TFT device with a structure for protecting the oxide semiconductor layer or a method for manufacturing the same, so as to prevent the oxide semiconductor layer from being damaged during the manufacturing of the device, and thus prevent the conductivity and structural integrity of the device from being reduced.

### SUMMARY OF THE INVENTION

One of technical problems to be solved in the present disclosure is that an oxide semiconductor is easily damaged by subsequent processes such as plasma vapor deposition and the like.

To solve the above-mentioned technical problems, the present disclosure provides a thin film transistor with a protective layer, including:

a substrate;

a gate electrode, a source electrode, and a drain electrode; and

an oxide semiconductor layer, wherein, the oxide semiconductor layer includes a source region and a drain region which electrically contact with the source electrode and the drain electrode respectively, and a channel region for providing a conductive channel between the source electrode and the drain electrode, wherein, a gate isolation layer is arranged between the oxide semiconductor layer and the gate region electrically contacting with the gate electrode, and an oxide semiconductor protective layer is arranged on the oxide semiconductor layer.

According to an embodiment of the present disclosure, relative to the substrate, the gate region electrically contacting with the gate electrode is arranged above the gate isolation layer.

According to an embodiment of the present disclosure, relative to the substrate, the gate region electrically contacting with the gate electrode is arranged below the gate isolation layer.

According to an embodiment of the present disclosure, a passivation layer is formed on the upper surfaces of the gate isolation layer and the gate electrode.

According to an embodiment of the present disclosure, a passivation layer is formed on the upper surfaces of the oxide semiconductor layer, the source electrode, and the drain electrode.

According to an embodiment of the present disclosure, the protective layer comprises an organic photosensitive crosslinked thin film.

According to an embodiment of the present disclosure, the oxide semiconductor protective layer serving as a mask and the oxide semiconductor layer are patterned at the same time.

According to an embodiment of the present disclosure, the whole oxide semiconductor layer is coated to form a protective layer after being patterned.

According to an embodiment of the present disclosure, the oxide semiconductor layer is an indium gallium zinc oxide layer.

According to another aspect of the present disclosure, a method for manufacturing a thin film transistor is also provided, including the following steps:

forming a substrate isolation layer on a substrate;

patterning, on the substrate isolation layer, an oxide semiconductor layer which includes a source region, a drain region, and a channel region;

forming on the source region and the drain region of the oxide semiconductor layer, a source electrode and a drain electrode contacting respectively therewith, so that the channel region is located between the source electrode and the drain electrode to serve as a conductive channel therebetween;

coating the whole exposed surface of the oxide semiconductor layer to form a protective layer;

forming a gate isolation layer on the source electrode and the drain electrode, the protective layer, and a part of the substrate isolation layer; and

forming a gate electrode on the gate isolation layer.

According to an embodiment of the present disclosure, a passivation layer is formed on the gate isolation layer and the gate through a CVD process.

According to an embodiment of the present disclosure, the gate isolation layer is formed through a PECVD process.

According to an embodiment of the present disclosure, the protective layer comprises an organic photosensitive crosslinked thin film.

According to a further aspect of the present disclosure, a method for manufacturing a thin film transistor is further provided, including the following steps:

forming, on a substrate, a substrate isolation layer;

patterning, on the substrate isolation layer, an oxide semiconductor layer which includes a source region, a drain region, and a channel region, by using a protective layer as a mask;

forming, on the source region and the drain region of the oxide semiconductor layer, a source electrode and a drain electrode contacting therewith respectively, so that the channel region is located between the source electrode and the drain electrode to serve as a conductive channel therebetween;

forming, on the source electrode and the drain electrode, the protective layer, and a part of the substrate isolation layer, a gate isolation layer; and

forming, on the gate isolation layer, a gate electrode.

According to a further aspect of the present disclosure, a method of manufacturing a thin film transistor is further provided, including the following steps:

forming, on a substrate, a substrate isolation layer;

forming, on the substrate isolation layer, a gate electrode;

forming, on the gate electrode and a part of the substrate isolation layer, a gate isolation layer;

forming, on the gate isolation layer, an oxide semiconductor layer which includes a source region, a drain region, and a channel region;

forming, on the source region and the drain region of the oxide semiconductor layer, a source electrode and a drain electrode contacting respectively therewith, so that the channel region is located between the source and the drain to serve as a conductive channel therebetween; and

coating the whole exposed surface of the oxide semiconductor layer to form a protective layer; and

forming, on the protective layer, a passivation layer.

According to an embodiment of the present disclosure, the passivation layer is formed on a part of the gate isolation layer, the protective layer, the source electrode, and the drain electrode through CVD process.

According to a further aspect of the present disclosure, a method of manufacturing a thin film transistor is further provided, including the following steps:

forming, on a substrate, a substrate isolation layer;

forming, on the substrate isolation layer, a gate electrode;

forming, on the gate electrode and a part of the substrate isolation layer, a gate isolation layer;

patterning, on the gate isolation layer by using a protective layer as a mask, an oxide semiconductor layer which includes a source region, a drain region, and a channel region;

forming, on the source region and the drain region of the oxide semiconductor layer, a source electrode and a drain electrode contacting respectively therewith, so that the channel region is located between the source electrode and the drain electrode so as to serve as a conductive channel therebetween; and

forming, on the protective layer, a passivation layer.

According to an embodiment of the present disclosure, the passivation layer is formed on a part of the gate isolation layer, the protective layer, and the source electrode and the drain electrode through CVD process.

In the transistor formed according to the technical solutions of the present disclosure, since the protective layer covers the upper surface and even both sides of the oxide protective layer, the protective layer can provide a comprehensive protection for the oxide semiconductor layer, and thus a better protective effect can be achieved.

Other features and advantages of the present disclosure will be illustrated in the following description, and are partially obvious from the description or understood through implementing the present disclosure. The objectives and other advantages of the present disclosure may be realized and obtained through the structures specified in the description, claims, and accompanying drawings.

### BRIEF DESCRIPTION OF THE DRAWINGS

The accompanying drawings are provided for further understanding of the present disclosure, constitute a part of the description, and are used for interpreting the present disclosure together with the embodiments of the present disclosure, rather than limiting the present disclosure. In the accompanying drawings:

FIG. 1a and FIG. 1b show structural diagrams of thin film transistor devices with a TGBC structure and a co-planar structure in the prior art;

FIG. 2a and FIG. 2b show first structures of forming protective layers on oxide semiconductor layers of a TGBC structure and a co-planar structure according to an embodiment of the present disclosure respectively; and

FIG. 3a and FIG. 3b respectively show second structures of forming protective layers on oxide semiconductor layers of a TGBC structure and a co-planar structure according to an embodiment of the present disclosure.

### DETAILED DESCRIPTION OF THE EMBODIMENTS

The embodiments of the present disclosure will be illustrated in detail in conjunction with the accompanying drawings and embodiments, and thus how technical means are applied to solve the technical problems and the implementation process of achieving the technical effects may be fully understood and accordingly implemented. It should be noted that as long as conflicts are avoided, all embodiments in the present disclosure and all features in all the embodiments may be combined together, and the formed technical solutions are within the scope of the present disclosure.

PECVD (Plasma Enhanced Chemical Vapor Deposition) is to ionize a gas containing thin film composition atoms by means of microwave, radio frequency or the like to locally form plasma which has strong chemical activity and easily reacts, so as to deposit a desired thin film on a substrate. In order that the chemical reaction may be performed at a relatively low temperature, the reaction is accelerated by using the activity of the plasma. In this case, the above CVD is also referred to as the Plasma Enhanced Chemical Vapor Deposition (PECVD).

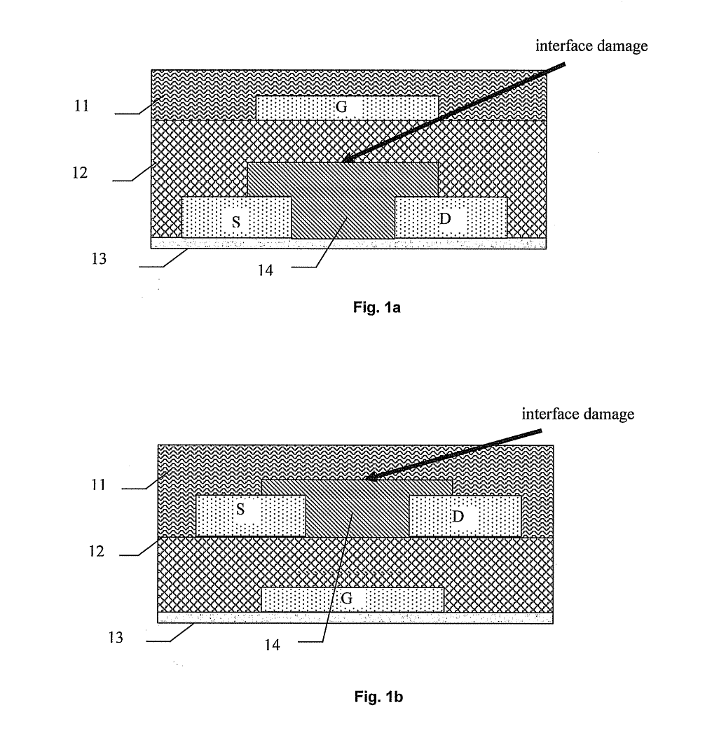

In the PECVD process, electrons moving at a high speed in the plasma collide with neutral reaction gas molecules which will accordingly become fragments or are in an activated state, and thus easily be reacted. A good SiOx or SiNx thin film may be obtained when the temperature of the substrate is generally kept at about 350° C., and may be used as a final passivation protective layer of an integrated circuit, thus improving the reliability of the integrated circuit. However, the implementation of the process may produce adverse influence on the conductivity of an oxide semiconductor material as mentioned above. For example, as shown in FIGS. 1a and 1b, in the subsequent GI CVD or PVCVD process, the adverse influence may be produced on an oxide semiconductor IGZO material layer.

Moreover, multiple steps of Photo Engraving Process (PEP for short) are needed for patterning a structure in the process of manufacturing a semiconductor device. The PEP in each step needs an expensive mask, which greatly increases the cost of manufacturing the device; and multiple times of repeating PEP increase the difficulty of the mutual alignment of structures, which results in increasing the difficulty of process and reduction of the yield of the device. Accordingly, to reduce the number of PEP steps is always an objective pursued in the industry of manufacturing semiconductor devices.

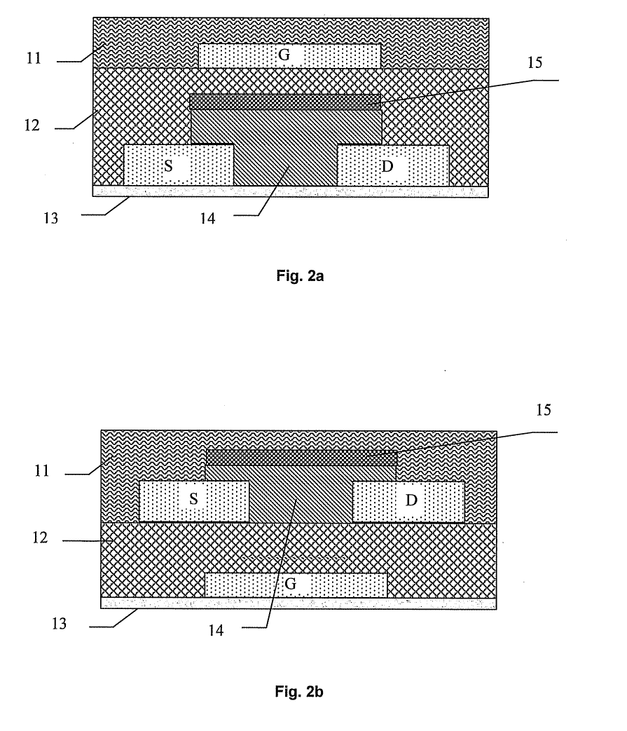

FIG. 2a shows a schematic diagram of a semiconductor device with a protective layer 15 based on the structure shown in FIG. 1a, according to an embodiment of the present disclosure.

This structure generally includes a substrate 13, a gate electrode G, a source electrode S, a drain electrode D, and an oxide semiconductor layer 14.

The oxide semiconductor layer 14 includes a resource region and a drain region electrically contacting with the source S and the drain D respectively, and a channel region configured to provide a conductive channel between the source electrode S and the drain electrode D. As shown in FIG. 2a, a gate isolation (GI) layer 12 is arranged between the oxide semiconductor layer 14 and a gate region for being in electric contact with a gate 103, and an oxide semiconductor protective layer 15 is arranged on the oxide semiconductor layer 14.

The oxide semiconductor protective layer 15 is configured to prevent subsequent processes such as a forming process of the GI layer 12 from affecting the oxide semiconductor and thus affecting the conductivity of the whole device.

As an example of the present disclosure, the protective layer 15 may be made of an organic photosensitive crosslinked thin film. The present disclosure is not limited to this, and the purpose of the present disclosure is to form protection on the oxide semiconductor so as to avoid sufferring the influence of the subsequent processes.

As shown in FIG. 2a, in the Top Gate Bottom Contact (TGBC for short) structure, the gate region in electrical contact with the gate electrode G is arranged above the GI layer 12 relative to the substrate 13. Finally, to protect the whole device, a passivation (PV) layer 11 is generally formed on the GI layer 12 and the upper surface of the gate region in contact with the gate electrode G.

The present disclosure is also applicable to a co-planar structure, as shown in FIG. 2b. In this structure, the gate region in electrical contact with the gate electrode G is arranged below the GI layer 12 relative to the substrate 13. Similarly, to protect the device, a PV layer 11 is finally formed on the oxide semiconductor layer 14 and the upper surfaces of the source region and the drain region in contact with the source electrode and the drain electrode.

To reduce the times of repeating PEP, it is the simplest way to pattern the oxide semiconductor protective layer serving as a mask and an oxide semiconductor material at the same time, so as to form the oxide semiconductor layer 14 with the protective layer 15.

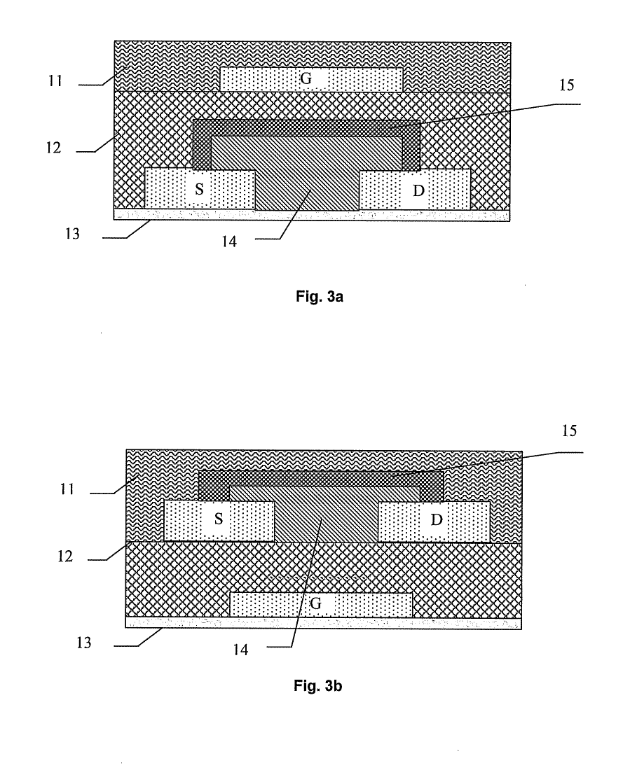

However, afterwards, although the upper surface of the oxide semiconductor layer 14 may be effectively protected, the lateral surfaces of the oxide semiconductor layer 14 may still be exposed in the subsequent CVD plasma environment. Accordingly, to provide comprehensive and reliable protection, it is feasible to coat the whole oxide semiconductor layer 14 so as to form the protective layer 15 after the oxide semiconductor layer is patterned, as shown in FIGS. 3a and 3b.

Any material for the oxide semiconductor layer may be well known by those skilled in the art, such as, but not limited to indium gallium zinc oxide (IGZO).

According to another aspect of the present disclosure, a method of manufacturing a thin film transistor is also provided, including the steps of:

forming a substrate isolation layer on a substrate;

patterning, on the substrate isolation layer, an oxide semiconductor layer including a source region, a drain region, and a channel region;

forming, on the source region and the drain region of the oxide semiconductor layer, a source electrode and a drain electrode contacting respectively therewith, so that the channel region is located between the source electrode and the drain electrode to serve as a conductive channel therebetween;

coating the whole exposed surface of the oxide semiconductor layer to form a protective layer;

forming a gate isolation layer on the source electrode and the drain electrode, the protective layer, and a part of the substrate isolation layer; and

forming a gate electrode on the gate isolation layer.

According to an embodiment of the present disclosure, a passivation layer is formed on the gate isolation layer and the gate electrode through a CVD process.

According to an embodiment of the present disclosure, the gate isolation layer is formed through a PECVD process.

According to an embodiment of the present disclosure, the protective layer is made of an organic photosensitive crosslinked thin film.

According to a further aspect of the present disclosure, a method of manufacturing a thin film transistor is further provided, including the following steps:

forming a substrate isolation layer on a substrate;

patterning, on the substrate isolation layer, an oxide semiconductor layer including a source region, a drain region, and a channel region, by using a protective layer as a mask;

forming a source electrode and a drain electrode on the source region and the drain region of the oxide semiconductor layer in a contact manner respectively, so that the channel region is located between the source electrode and the drain electrode to serve as a conductive channel therebetween;

forming a gate isolation layer on the source electrode and the drain electrode, the protective layer, and a part of the substrate isolation layer;

forming a gate on the gate isolation layer.

According to a further aspect of the present disclosure, a method of manufacturing a thin film transistor is further provided, including the following steps:

forming a substrate isolation layer on a substrate;

forming a gate on the substrate isolation layer;

forming agate isolation layer on the gate electrode and a part of the substrate isolation layer;

forming, on the gate isolation layer, an oxide semiconductor layer including a source region, a drain region, and a channel region;

forming a source and a drain on the source region and the drain region of the oxide semiconductor layer in a contact manner respectively, so that the channel region is located between the source and the drain to serve as a conductive channel therebetween;

coating the whole exposed surface of the oxide semiconductor layer to form a protective layer; and

forming a passivation layer on the protective layer.

According to an embodiment of the present disclosure, the passivation layer is formed on a part of the gate isolation layer, the protective layer, and the source electrode and the drain electrode through a CVD process.

According to a further aspect of the present disclosure, a method of manufacturing a thin film transistor is further provided, including the following steps:

forming a substrate isolation layer on a substrate;

forming a gate electrode on the substrate isolation layer;

forming a gate isolation layer on the gate electrode and a part of the substrate isolation layer;

patterning, on the gate isolation layer, an oxide semiconductor layer including a source region, a drain region, and a channel region, by using a protective layer as a mask;

forming a source electrode and a drain electrode on the source region and the drain region of the oxide semiconductor layer in a contact manner respectively, so that the channel region is located between the source electrode and the drain electrode to serve as a conductive channel therebetween;

forming a passivation layer on the protective layer.

According to an embodiment of the present disclosure, the passivation layer is formed on a part of the gate isolation layer, the protective layer, the source and the drain through a CVD process.

Although the embodiments are described above, the foregoing are merely the embodiments for facilitating the understanding of the present disclosure, rather than limiting the present disclosure. Any changes or alternatives conceived by the skilled ones in the art after reading the content disclosed herein will fall within the scope of the present disclosure. Accordingly, the scope of the present disclosure will be defined in the accompanying claims.

1. A thin film transistor, including:
a substrate;
a gate electrode, a source electrode, and a drain electrode; and
an oxide semiconductor layer,
wherein the oxide semiconductor includes a source region and a drain region which electrically contact with the source electrode and the drain electrode respectively, and a channel region for providing a conductive channel between the source electrode and the drain electrode, and
a gate isolation layer is arranged between the oxide semiconductor layer and the gate region electrically contacting with the gate electrode, and an oxide semiconductor protective layer is arranged on the oxide semiconductor layer.

2. The thin film transistor according to claim 1, wherein relative to the substrate, the gate region in electrical contact with the gate electrode is arranged above the gate isolation layer.

3. The thin film transistor according to claim 1, wherein relative to the substrate, the gate region electrically contacting with the gate electrode is arranged below the gate isolation layer.

4. The thin film transistor according to claim 2, wherein a passivation layer is formed on the upper surfaces of the gate isolation layer and the gate electrode.

5. The thin film transistor according to claim 3, wherein a passivation layer is formed on the upper surfaces of the oxide semiconductor layer, the source electrode, and the drain electrode.

6. The thin film transistor according to claim 1, wherein the protective layer comprises an organic photosensitive crosslinked thin film.

7. The thin film transistor according to claim 6, wherein the oxide semiconductor protective layer serving as a mask and the oxide semiconductor layer are patterned at the same time.

8. The thin film transistor according to claim 6, wherein the whole oxide semiconductor layer is coated to form a protective layer after being patterned.

9. The thin film transistor according to claim 6, wherein the oxide semiconductor layer is an indium gallium zinc oxide layer.

10. The thin film transistor according to claim 2, wherein the protective layer comprises an organic photosensitive crosslinked thin film.

11. The thin film transistor according to claim 3, wherein the protective layer comprises an organic photosensitive crosslinked thin film.

12. A method of manufacturing a thin film transistor, including steps of:
forming, on a substrate, a substrate isolation layer;
patterning, on the substrate isolation layer, an oxide semiconductor layer which includes a source region, a drain region, and a channel region;
forming, on the source region and the drain region of the oxide semiconductor layer, a source electrode and a drain electrode contacting respectively therewith, so that the channel region is located between the source electrode and the drain electrode to serve as a conductive channel therebetween;
coating the whole exposed surface of the oxide semiconductor layer to form a protective layer;
forming a gate isolation layer on the source electrode and the drain electrode, the protective layer, and a part of the substrate isolation layer; and
forming a gate electrode on the gate isolation layer.

13. The method according to claim 12, wherein a passivation layer is formed on the gate isolation layer and the gate through CVD process.

14. The method according to claim 12, wherein the gate isolation layer is formed through PECVD process.

15. The method according to claim 12, wherein the protective layer comprises an organic photosensitive crosslinked thin film.

16. (canceled)

17. A method of manufacturing a thin film transistor, including steps of:
forming, on a substrate, a substrate isolation layer;
forming, on the substrate isolation layer, a gate electrode;
forming, on the gate electrode and a part of the substrate isolation layer, a gate isolation layer;
forming, on the gate isolation layer, an oxide semiconductor layer which includes a source region, a drain region, and a channel region;
forming, on the source region and the drain region of the oxide semiconductor layer, a source electrode and a drain electrode contacting respectively therewith, so that the channel region is located between the source electrode and the drain electrode to serve as a conductive channel therebetween; and
coating the whole exposed surface of the oxide semiconductor layer to form a protective layer; and
forming, on the protective layer, a passivation layer.

18. The method according to claim 17, wherein the passivation layer is formed on a part of the gate isolation layer, the protective layer, the source electrode, and the drain electrode through CVD process.

19-20. (canceled)
